(19) United States
(12) Patent Application Publication
(10) Pub. No.: US 2009/0248326 A1
(43) Pub. Date: Oct. 1, 2009

(54) VIBRATION SENSOR

(75) Inventor: DOUGLAS CHRISTIAN GREENING, Calgary (CA)

Correspondence Address: BENNETT JONES LLP;C/O MS ROSEANN CALDWELL, 4500 BANKERS HALL EAST, 855 - 2ND STREET, SW, CALGARY, AB, T2P 4K7, CA

(73) Assignee: BOSS PACKAGING INC., Calgary (CA)

(21) Appl. No.: 12/170,217

(22) Filed: Jul. 9, 2008

Related U.S. Application Data
(60) Provisional application No. 61/041,413, filed on Apr. 1, 2008.

(51) Int. Cl. G06F 19/00; G01P 15/00; G01R 33/07

(52) U.S. Cl. 702/56; 702/141; 324/207.2

(57) ABSTRACT

A vibration sensor includes a housing, a high G accelerometer installed in the housing to measure vibratory accelerations communicated to the housing; a low G accelerometer installed in the housing to measure vibratory accelerations communicated to the housing; and a processor installed within the housing to receive data from the high G accelerometer and the low G accelerometer. A method for using the vibration sensor includes employing the low G and the high G acceleration data. Another vibration sensor includes intrinsically safe buttons.

### FIELD

The present invention relates to vibration sensors.

### BACKGROUND

Some heavy stationary machinery that include rotating or reciprocating parts such as motors and compressors operate with a regular vibration output. However, when a breakdown event or an event leading to a breakdown event occurs, such an event may be indicated by a vibratory anomaly. For example, shaft or vane cracking or breaking may result in the generation of a vibratory shock. Thus, it may be useful to monitor the vibration activity of heavy stationary machinery. Vibration sensors may be used for this purpose.

### SUMMARY

In accordance with a broad aspect of the present invention, there is provided a vibration sensor comprising: a housing, a high G accelerometer installed in the housing to measure vibratory accelerations communicated to the housing; a low G accelerometer installed in the housing to measure vibratory accelerations communicated to the housing; and a processor installed within the housing to receive data from the high G accelerometer and the low G accelerometer.

In accordance with another broad aspect of the present invention, there is provided a method for monitoring vibrational energy on a machine, the method comprising: installing a vibration sensor on the machine, the vibration sensor including: a high G accelerometer to measure vibratory accelerations; a low G accelerometer to measure vibratory accelerations; and a processor to receive data from the high G accelerometer and the low G accelerometer; receiving high G acceleration data from the high G accelerometer, receiving low G acceleration data from the low G accelerometer, and manipulating the high G accelerometer data and the low G accelerometer data to obtain acceleration and velocity and/or displacement on vibrational events of interest.

In accordance with another broad aspect of the present invention, there is provided a vibration sensor comprising: a housing including an outer surface and an inner surface defining an inner volume; electronics in the inner volume of the housing for sensing and analyzing vibrational energy communicated to the housing; and an intrinsically safe actuation button including a hall effect sensor in the inner volume, a button body installed on the housing and accessible on the outer surface of the housing, the button body being moveable toward and away from the hall effect sensor while remaining outwardly of the inner volume and a magnet carried on the button body and moveable with the button body toward and away from the hall effect sensor to actuate the hall effect sensor.

### FIGURES

Referring to the drawings, several aspects of the present invention are illustrated by way of example, and not by way of limitation, in detail in the figures, wherein:

FIG. 1 is a schematic, front elevation view of a vibration sensor mounted on a piece of machinery.

FIG. 2 is an enlarged front perspective view of another vibration sensor.

FIG. 3 is an exploded, perspective view of a vibration sensor.

FIG. 4 is a schematic functional diagram of a vibration sensor.

FIGS. 5a and 5b are exploded and side elevation/sectional views, respectively, of an actuator button.

FIG. 6 is a flowchart showing a method of sensing a vibration event of interest.

### DETAILED DESCRIPTION OF VARIOUS EMBODIMENTS

The detailed description set forth below in connection with the appended drawings is intended as a description of various embodiments of the present invention and is not intended to represent the only embodiments contemplated by the inventor. The detailed description includes specific details for the purpose of providing a comprehensive understanding of the present invention. However, it will be apparent to those skilled in the art that the present invention may be practiced without these specific details.

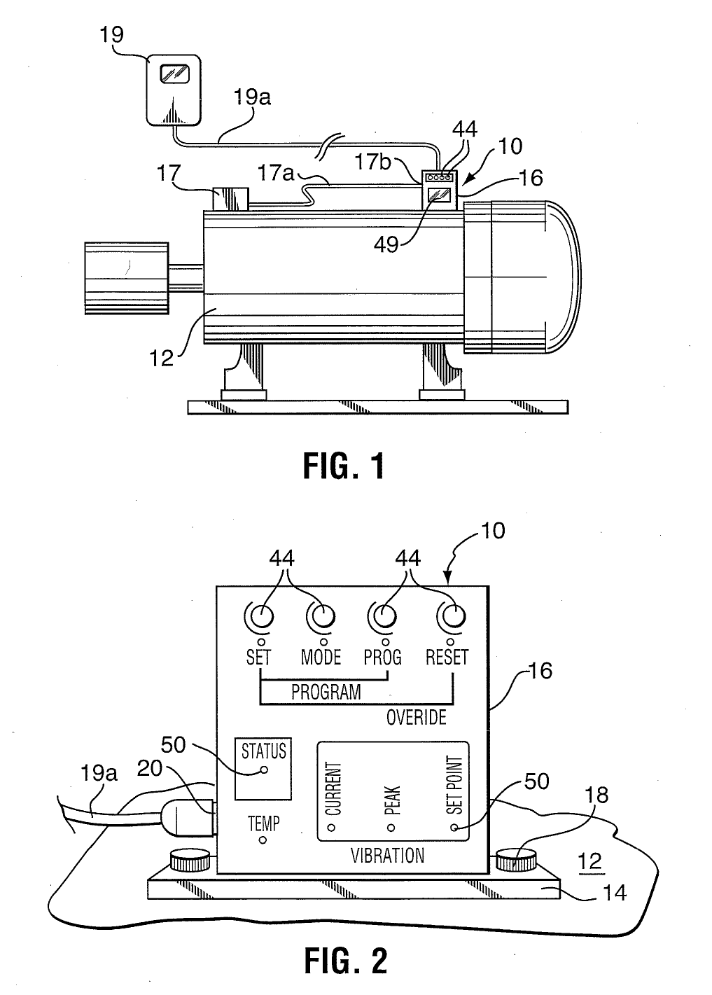

Similar parts on some drawings are indicated with identical or similar series numbers in order to facilitate comparison between drawings and understanding of the invention. For example, although FIGS. 1, 2 and 3 show different embodiments of the invention and it is apparent that various features of the illustrated devices differ, identical numbering is used for the parts.

With reference to FIGS. 1 to 3, a vibration sensor 10 may be used to monitor the condition of one or more pieces of heavy stationary machinery 12, such as gas compressors, ballast tanks, cooling towers, motors, etc. When an event leading to a breakdown occurs, such as a piston failure in a gas compressor or a bearing failure in a motor, such a breakdown event or warming event may be indicated by a vibratory anomaly. As such, vibration sensor 10 may be used to determine when service is required to address or avoid a breakdown.

Vibration sensor 10 may be provided to be mountable on heavy machinery 12, but which is non-intrusive. Sensor 10 may operate to monitor the condition of machinery, without penetrating the machinery. In particular, sensor 10 operates by monitoring the vibrational output of the machinery provided its one or more vibration sensing device is mounted in communication with the vibrational output of the machinery.

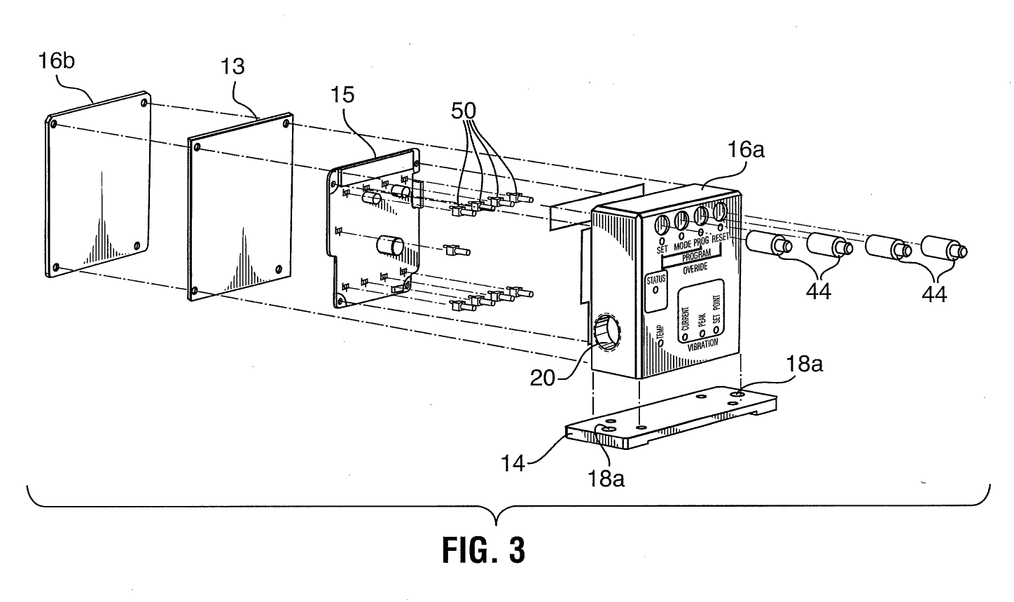

In one embodiment, sensor 10 includes a base 14 and a housing 16 (shown as a front and a back housing parts 16a, 16b in FIG. 3) rigidly connected such that any movement of the base is transferred directly to the housing. Base 14 is formed for mounting onto the machinery 12 to be monitored, for example, by threaded fasteners 18 such as bolts or anchors through apertures 18a, welding, etc. Base 14 may be formed to closely follow the surface contour of the machinery 12 outer case or vice versa such that there is a close fit between the base and the machinery, such close fit ensuring that vibrational energy output from the machinery is communicated efficiently to the sensor.

Housing 16 accommodates electronics and devices 15 for one or more of powering, control, vibrational sensing, memory and data analysis. Sensor 10 may include fully potted, solid state electronics such that there are few if any moving parts to fail and provide an intrinsically safe device with reduced explosion risk. Potting may include filling the housing with epoxy or other polymer to embed the components within the polymer. In another embodiment, sensor 10 may have its settings modified by magnetically activated parts that avoid explosive risk. A gasket 13 may be employed to seal the interior housing against infiltration by damaging fluids.

Sensor 10 may provide vibrational monitoring in a plurality of planes of motion. For example, in one embodiment, vibration sensor 10 may be equipped to provide 3-dimensional vibrational feedback. Thus, the sensor is capable of detecting the event, regardless of the direction of the vibratory event generated by the machinery. In one embodiment, for example, the vibration sensor may include a plurality of accelerometers to analyze in x, y and z axis. As will be appreciated, this can be achieved by employing one or more multiple axis accelerometers or a plurality of accelerometers each measuring in one axis. The sensor may include a fully configurable G range that can be accurate to greater than ±0.02 G below 10 G and ±0.5 G below 50 G.

In one embodiment, at least one accelerometer measuring in each axis is installed in housing 16. Such accelerometers may be installed rigidly within the housing such that any vibration affecting the housing will be conveyed efficiently to the accelerometers. In one embodiment, potting is useful to effectively communicate vibrational energy from the housing to the accelerometers, as the potting creates a unitary mass between the housing and the electronics.

In one possible embodiment, one or more external accelerometer units 17 may be installed external to housing and each connected to sensor 10 by a communication line 17a. Transmission of a signal along lines 17a can be adversely effected by noise. Such external accelerometers, therefore, can have analog to digital converters installed in their housings such than any signal communicated along line 17a is digital. As such, the length of communication lines can be of a length longer than that selected for analog signal transmission. For example, data transfer can be achieved over lines of up to 500 meters without significant data loss. Communication line 17a may be removably connected to the sensor by an outlet 17b accessible on the housing 16.

The sensor may be connected for download of data, communications and/or external control as by use of a controller 19 with a communications line 19a connectable into a port 20. While it is desirable that all installed components such as sensor 10 and external accelerometer units 17 offer intrinsic safety, controller 19, being temporarily connectable and/or remotely operable need not be selected for intrinsic safety. As an example, one useful controller may be a BossPac Bluebox™ Controller, available from the assignee of this application.

Sensor 10 may include user interface such as buttons 44 for input of information and control through selectors, toggles, a key pad, etc. and/or a display such as a screen 49, one or mores indicator lights 50, for example LEDs of one or more colors, etc. to provide instant user feedback at the sensor.

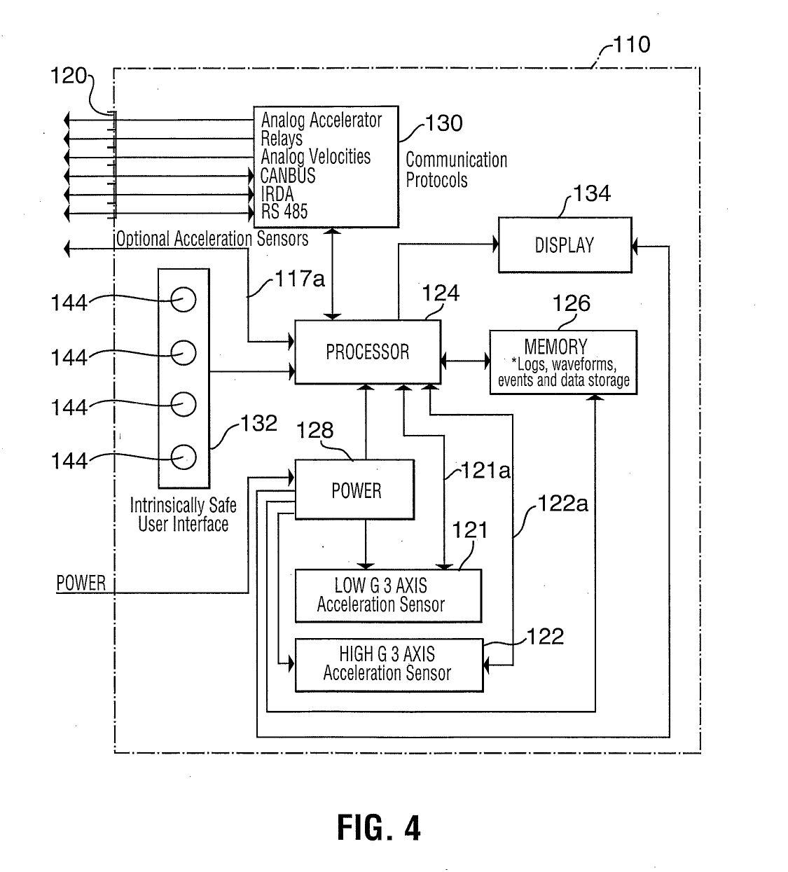

In one embodiment, as shown in FIG. 4, a sensor 110 may include one or more low G accelerometers 121 and one or more high G accelerometers 122. As will be appreciated, a low G accelerometer may operate to measure vibratory energy at less than 10 G to 15 G and a high G accelerometer may operate best to measure vibratory energy of more than 10 G up to 50 G. Low G accelerometers have less noise. By use of a combination of low G and high G accelerometers, high G vibrations can be sensed without sacrificing low G sensitivity. In such an embodiment, the sensor may include one or more low G accelerometers to measure in the x, y and z axis and at least one high G accelerometer. In one embodiment, in addition to low G accelerometers, at least one high G accelerometer is included to measure in each of the x, y and z axis to give good resolution of data over a large G range.

The accelerometers used in sensor 110 can be selected to generate analog or digital signals. Since digital signals are less effected by noise, digital output is of greatest interest. As such, digital accelerometers may be selected or analog to digital converters may be used to manipulate the signal close to the accelerometers before transmission. As will be appreciated, accelerometers may be employed that are packaged as chips.

Vibration sensor 110 may further include devices and/or electronics such as for example, a processor 124, a memory 126, a power supply system 128, a data communication system 130, user interfaces such as user input selectors 132 and/or a display 134.

Processor 124 may be a central processing unit, programmable logic controller, digital signal processor, etc. that controls the general operation of the sensor components including the receipt and processing of data and the output of signal and information based on the data. For example, processor 124 may also include a function for recognizing data indicative of critical vibratory events and communicating with a machinery controller for signaling a shut down. The processor can be programmed to carry out its various functions, as will be well understood by a person skilled in the art.

Processor 124 may receive signals from or sample the accelerometers 121, 122, as through connections 121a, 122a, or external accelerometers through connection 117a and may filter and process data and may log vibration data to on-board memory 126. Memory 126, for example, may include non-volatile RAM memory which will retain stored information even if power is removed from the system. A 16 or 32 megabit memory capability may be useful to allow data storage for later downloads and development of waveform output. Data may be stored as raw, time-based waveforms.

Power and data communications such as power output, data transfer and control inputs/outputs can be achieved via a data communication system 130. System may include any communication system, as desired, and for example may support analog or digital communications including any or all communication protocols of CANBUS, IRDA, RS485, etc. In one embodiment, IRDA protocol may provide wave form transferring capabilities. This provides a wireless link to allow uploads of data, for example, wave form data from memory even in a potentially hazardous environment. Digital NC/NO signals can be used for communication to an analyzer or controller, as desired. Output signals can be provided such as for control of machinery through relays, etc. External connections to data communication system 130 may be provided through one or more ports 120.

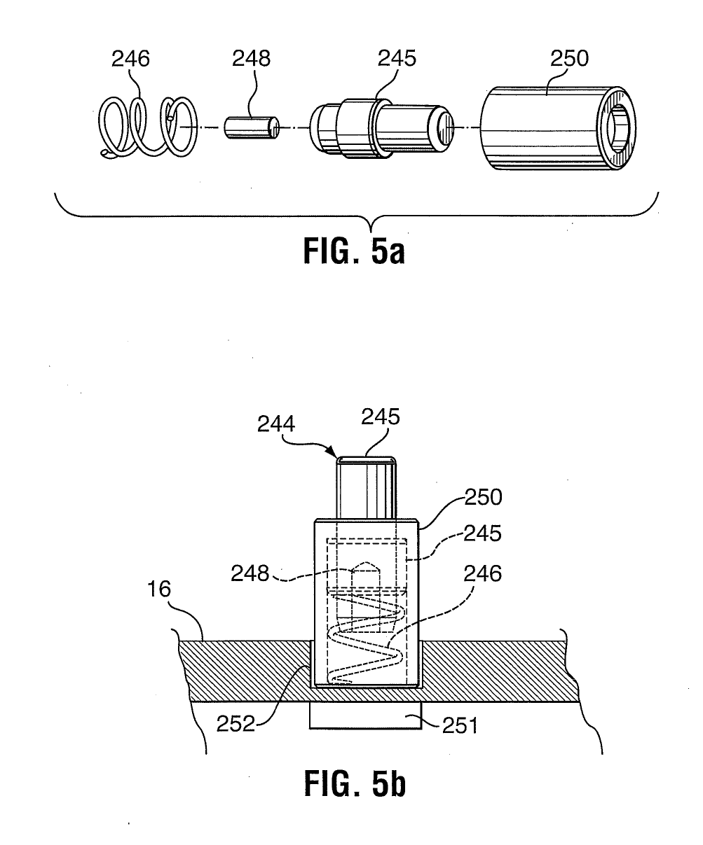

Direct programming and control may be affected by user input selectors 132 such as exterior control buttons 144 positioned for control from exterior of sensor housing 16. Such buttons 144 may include mechanisms selected for intrinsic safety, where it is desired to achieve a higher rating for use in explosion risk environments. In one embodiment, intrinsically safe buttons may operate based on magnetic activation. With reference to FIG. 5, for example, one embodiment of an intrinsically safe button 244 may be of the push button type including a button body 245 that carries a magnetic insert 248 on its inner end and telescopically moves in a sleeve 250. A biasing spring 246 biases the body into a protruding position from the sleeve away from housing 16. Spring 246 can be compressed against its spring force to allow the body to be urged to penetrate further into sleeve 250, in so doing moving insert 248 deeper into the sleeve towards housing. Sleeve 250 is mounted in an indentation 252 on sensor housing 16. The button is mounted to act with a Hall Effect sensor 251 inside the sensor housing 16 beneath blind hole 252. Magnetic insert 248 actuates Hall Effect sensor 251 when the magnetic field of the insert is brought into proximity with its Hall Effect sensor. The insert is moved into and out of proximity with the Hall Effect sensor by being pushed into and biased outwardly relative to sleeve. With such buttons, no button component need penetrate the housing so that the inner components of the sensor remain isolated from the housing exterior envelope. Of course, the housing should be constructed from a non-ferrous material such as aluminum, stainless steel or plastic that will not interfere with or overly facilitate conduction of the magnetic field from the insert to the Hall Effect sensor. For example, a housing of mild steel may not be most useful, as such a material may allow transmission of the magnetic field before the button was depressed. The buttons may offer an adjustable override selection that may act as a reset function, actuation of one or more buttons or toggling through settings can be used to analyze detected events, set filtering limits, set shut down levels, enter addresses for communications, etc.

Display 134 may be provided to allow instant user feedback at the sensor. Display 134 may include a screen, indicator lights, audible signals, etc.

Sensor 110 may operate on 8 to 24 volt DC power source 128, if desired, or other power sources such as those powering the machinery, as by connection through outlet 156. Power may be provided to the processor, memory, display, and accelerometers.

In order to sense a vibration event of interest on a monitored piece of machinery, the sensor and any optional accelerometers are mounted on the machine. When the system is powered, accelerometer data may be communicated to the processor, as by the processor sampling the accelerometers regularly for example at rates greater than 1 kHz and in some cases greater than 200 kHz. If the accelerometers are not linked directly to an analog to digital converter, the processor may act to convert the analog signal to a digital signal. The processor may then manipulate the accelerometer data. For example, the processor may perform any or various combinations of the following: data filtering, data logging, data analysis including selection of events of interest, data integration, data output or signal output based on data analysis.

In one embodiment, accelerometer data and/or integrated data are stored. To facilitate data storage, baseline data may not be selected for longer term storage. For example, to permit sensor operation with a reasonable storage capacity and without constant user involvement, only events beyond a selected level are retained longer term in on-board memory (i.e. not overwritten, erased, etc. until the data is appropriately dealt with). Data retrieved from the accelerometers may be reviewed to determine if a signal beyond a selected value occurs and, therefore, if the data should be kept or dumped (i.e. deleted, overwritten, etc.). For any event of interest, it is desired to have an amount of data relating to a period of time before and possibly after the event. Thus, data is held in memory for a selected period of time until it is determined whether or not an event of interest occurred in that period. For example, in one procedure data retrieved in a selected time interval is logged by the processor but will be dumped if the data includes no signal beyond a selected value during that time interval. However, if during the selected time interval a vibratory event generates a signal beyond the selected amplitude value, the logged data over the selected interval is preserved in on-board memory until it can be appropriately dealt with (i.e. transferred, analyzed, used to generate output signals or information, etc.). In addition, data obtained over a following interval may also be transferred to memory such that a window of data is stored around an event of interest. The selected interval may be, for example, 0.05 to 10 seconds. Such intervals may be rolling rather than discrete.

Events of interest may be generated by a vibratory anomaly, perhaps indicating a failure or an event that may lead to a failure, or may be generated by machine start up or shut down, during which times it is more commonly possible for there to be increased levels of machine vibration.

In one embodiment, in addition to, or alternately, data logging can occur at specified times such as during machine start up or shut down, even if no data surpasses the selected value. For example, the processor may be programmed to preserve data in memory for a selected period after the machinery is started up. Start up can be sensed when the accelerometer data abruptly increases from substantially no vibration (i.e. machine not working) to some selected amount of vibration indicative of machinery function.

The processor may allow on board data manipulation to output control or communication signals. For example, in one embodiment, the heavy machinery monitored by the sensor may be controlled directly by a machine controller linked directly or through another controller to the sensor. In one such an embodiment, the sensor may be programmed with settings to monitor for events of interest, to perform on-board analysis and to output shutdown signals to the machine controller in communication with the machinery being monitored, all in accordance with those programmed settings. Shutdown signals may cause the machine controller to remove power from the machine or operate in another way to cause a machine shutdown. Shutdown signals may be based on large shock loads or integrated velocity values. As noted above, start up may be a period of normally high vibration. The processor can be set to allow an override on start up such that rough running of the machine does not cause a shutdown signal to be output. Settings for the sensor are programmable from a central control, preprogramming and/or directly at the sensor. Shutdown events may also be combined with data logging in pre and post event intervals, as described above, such that data generating shutdown events can be later analyzed.

Stored data may be raw waveform data including time and amplitude, for example, in the form of a pulse code modulation signal. In one embodiment, for example, the accelerometer data, which may simply be measured acceleration, may be manipulated to also generate velocity and/or displacement. In such an embodiment, it is useful to obtain data from low G accelerometers. For example, high G accelerometers may sense shocks well, but a combination of high G and low G accelerometers may be useful to mitigate the effects of noise in further analysis. Data from low G accelerometers is particularly useful for manipulation to generate velocity and displacement measurements. In one embodiment, for example, acceleration data from as many of the x, y and z axis low G accelerometers as possible may integrated to arrive at velocity and displacement and high G sensors may be sampled to measure acceleration. Amplitudes for any of acceleration, velocity and/or displacement can be added from the x, y and z axis to obtain single total values for any event. Data from low G and high G accelerometers can be obtained and combined as desired to select the best data for analyzing low G and high G events. In a transition between low and high G events, a weight average of the two data supplies can be employed.

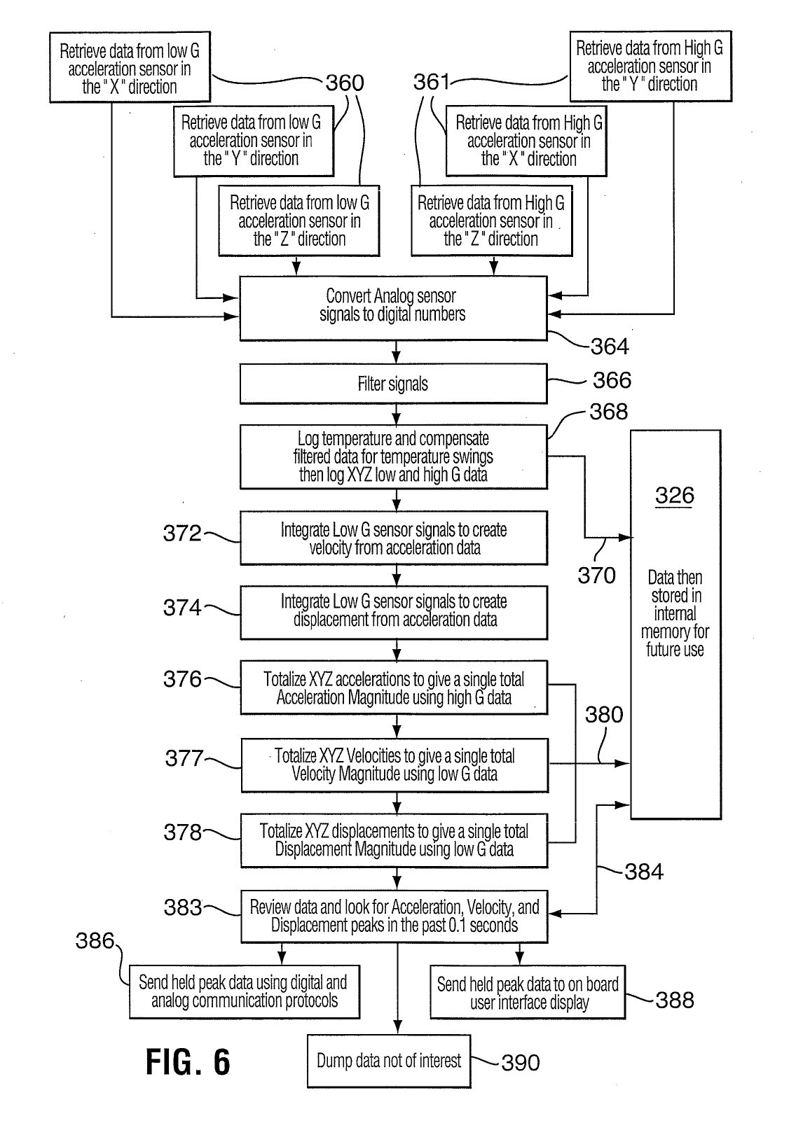

FIG. 6 illustrates, by use of a flowchart, one possible method of sensing a vibration event of interest generated by a rotating machine. The processor can retrieve data from the accelerometers. For example, the processor can sample 360 any low G accelerometers and sample 361 any high G accelerometers at regular intervals. This may include, for example, retrieving data with respect to at least some of the x, y and z axis from both high G and low G accelerometers. Signal communication or sampling may occur at a very rapid rate such as every millisecond, or even more frequently such as every 1 to 20 microseconds. Thus, even an event of very short duration should be detectable. The processor can control the sampling rate. The sensor's processor may allow for down sampling to slow output to allow for communication with controllers that perhaps operate at slower sampling speeds than the operational speed of the sensor's systems. For example, the sensor can hold peak waveforms so that a controller that samples at slower rates can detect a record of the vibration.

Analog signals from the accelerometers may then be converted 364 to digital signals. If desired, this may be done adjacent the accelerometers before signal transmission such that signal degradation from communication of analog signals can be avoided.

At the processor, signals are filtered 366 to smooth the data, as by use of a rolling average, or other means which will be appreciated by a skilled person, etc. Temperature may be sensed and logged 368 to compensate filtered data for temperature swings. Thereafter, the accelerator data is logged 370 to memory 326. Data may be recorded which is useful to generate raw waveforms. Data logging 370 can occur continuously or only during specified periods including, for example, during start up or shut down. High resolution logging, including the storage into memory of complete waveforms can be obtained during the periods of interest such as after start up and pre and post shut down.

In the illustrated embodiment, the processor then also can analyze the data from the accelerometers. For example, the low G acceleration signal data can be integrated to determine velocity 372 and displacement 374. Accelerations and calculated velocity and displacements can be totalized 376, 377, 378 to arrive at single values quantifying any vibratory event that was not filtered out. Such values can then be logged 380 to memory 326.

Generally, during normal machinery operations, it may be problematic to preserve baseline data. Baseline data without anomalies may not be of much value for machine diagnostics and, therefore, may not be preserved in memory. However, event data that exceeds set values may be recorded, including data relevant to the vibration waveform of an irregularity. The processor can review logged data for quantified values over selected periods such as in 0.05 to 1 second intervals and select 382 that data relating to events of interest. For example, in the illustrated method, the data is reviewed 383 in rolling periods of 0.1 seconds to determine peaks of interest as determined by the processor through programmed settings. Data relating to peaks of interest may be returned 384 to memory 326. Alternately or in addition, the data, control signals or warning communications may be sent 386 externally, for example to a machinery controller or controller 19, via the sensor's data communication system and/or sent 388 to the sensor's display. Baseline data, which is data without processor-identified events of interest, may then be dumped 390.

This method may be repeated continuously during operation of the sensor.

The previous description of the disclosed embodiments is provided to enable any person skilled in the art to make or use the present invention. Various modifications to those embodiments will be readily apparent to those skilled in the art, and the generic principles defined herein may be applied to other embodiments without departing from the spirit or scope of the invention. Thus, the present invention is not intended to be limited to the embodiments shown herein, but is to be accorded the fall scope consistent with the claims, wherein reference to an element in the singular, such as by use of the article “a” or “an” is not intended to mean “one and only one” unless specifically so stated, but rather “one or more”. All structural and functional equivalents to the elements of the various embodiments described throughout the disclosure that are know or later come to be known to those of ordinary skill in the art are intended to be encompassed by the elements of the claims. Moreover, nothing disclosed herein is intended to be dedicated to the public regardless of whether such disclosure is explicitly recited in the claims. No claim element is to be construed under the provisions of 35 USC 112, sixth paragraph, unless the element is expressly recited using the phrase “means for” or “step for”.

1. A vibration sensor comprising: a housing, a high G accelerometer installed in the housing to measure vibratory accelerations communicated to the housing; a low G accelerometer installed in the housing to measure low G vibratory accelerations communicated to the housing; and a processor installed within the housing to receive data from the high G accelerometer and the low G accelerometer.

2. The vibration sensor of claim 1 further comprising sufficient low G accelerometers to obtain low G acceleration data in the x, y and z axis.

3. The vibration sensor of claim 1 further comprising sufficient high G accelerometers to obtain high G acceleration data in the x, y and z axis.

4. The vibration sensor of claim 1 wherein the processor is programmed to calculate at least one of velocity and displacement based on the low G vibratory accelerations.

5. The vibration sensor of claim 1 further comprising a data communication system installed in the housing capable of handling IRDA wave forms.

6. The vibration sensor of claim 1 further comprising on-board, non-volatile RAM memory installed in the housing.

7. The vibration sensor of claim 6 wherein the processor is programmed to log raw time based vibrational data to the memory.

8. A method for monitoring vibrational events of a machine, the method comprising: installing a vibration sensor on the machine, the vibration sensor including: at least one high G accelerometer to measure vibratory accelerations; at least one low G accelerometer to measure vibratory accelerations; and a processor to receive data from the high G accelerometer and the low G accelerometer; receiving high G acceleration data from the at least one high G accelerometer, receiving low G acceleration data from the at least one low G accelerometer, and manipulating the high G accelerometer data and the low G accelerometer data to obtain acceleration and at least one of velocity and displacement on vibrational events of interest.

9. The method of claim 8 wherein receiving low G acceleration data includes measuring accelerations in the x, y and z axis using the at least one low G accelerometer.

10. The method of claim 8 wherein receiving high G acceleration data includes measuring accelerations in the x, y and z axis using the at least one high G accelerometer.

11. The method of claim 8 further comprising analyzing accelerations of less than 15 G using the at least one low G accelerometer.

12. The method of claim 8 further comprising analyzing accelerations of greater than 10 G using the at least one high G accelerometer.

13 The method of claim 8 further comprising analyzing accelerations of 5 to 20 G using a combination of the high G accelerometer data and the low G accelerometer data.

14. The method of claim 8 wherein manipulating data includes integrating the low G accelerometer data to obtain velocity and displacement on vibrational events of interest.

15. A vibration sensor comprising: a housing including an outer surface and an inner surface defining an inner volume; electronics in the inner volume of the housing for sensing and analyzing vibrational energy communicated to the housing; and an intrinsically safe actuation button including a hall effect sensor in the inner volume in communication with the electronics, a button body installed on the housing and accessible on the outer surface of the housing, the button body being moveable toward and away from the hall effect sensor while remaining outwardly of the inner volume and a magnet carried on the button body and moveable with the button body toward and away from the hall effect sensor to actuate the hall effect sensor.

16. The vibration sensor of claim 15 wherein the button body is spring biased to normally urge the button body away from the Hall Effect sensor.

17. The vibration sensor of claim 15 wherein the electronics and the Hall Effect sensor are potted within the inner volume of the housing.

18. The vibration sensor of claim 15 wherein the housing includes a first part and a second part and the vibration sensor further comprises a gasket to seal between the first part and the second part.
